(19) United States
(12) Patent Application Publication
(10) Pub. No.: US 2013/0104977 A1
(43) Pub. Date: May 2, 2013

(54) SOLAR CELL, SOLAR CELL WITH INTERCONNECTION, SOLAR CELL MODULE, AND METHOD OF MANUFACTURING SOLAR CELL WITH INTERCONNECTION

(71) Applicants: Kenji Yasutake, Osaka-shi (JP); Yasushi Sainoo, Osaka-shi (JP)

(72) Inventors: Kenji Yasutake, Osaka-shi (JP); Yasushi Sainoo, Osaka-shi (JP)

(73) Assignee: SHARP KABUSHIKI KAISHA, Osaka-shi, Osaka (JP)

(21) Appl. No.: 13/807,992

(22) PCT Filed: Jun. 24, 2011
(86) PCT No.: PCT/JP2011/064526

§ 371 Date: Jan. 2, 2013

(30) Foreign Application Priority Data
Jul. 1, 2010 (JP) 2010-151071

(51) Int. Cl. H01L 31/0224; H01L 31/18

(52) U.S. Cl. CPC H01L 31/022441; H01L 31/18
USPC 136/256; 438/98

(57) ABSTRACT

A solar cell (8), a solar cell with an interconnection, a solar cell module, and a method of manufacturing the solar cell with an interconnection are provided. The solar cell (8) includes a substrate (1), a first electrode (6, 7) disposed on one of surfaces of the substrate (1), a first covering layer (66, 67) covering the surface of the first electrode (6, 7). The first covering layer (66, 67) is made of a material by which ion migration is less likely occur as compared with a metal material forming the first electrode (6, 7).

### TECHNICAL FIELD

The present invention relates to a solar cell, a solar cell with an interconnection, a solar cell module, and a method of manufacturing a solar cell with an interconnection.

### BACKGROUND ART

In recent years, from the viewpoint of global environmental problems, such as a problem of the exhaustion of energy resources and an increase in CO₂ in the atmosphere, clean energy has been desired to be developed. Solar photovoltaic power generation using, in particular, solar cells has been developed and put into practical use as a new energy source, and is now on the way to progress.

A double-sided electrode type solar cell has been a conventional mainstream solar cell, which includes for example a monocrystalline or polycrystalline silicon substrate having a light receiving surface on which impurities opposite in conductivity type to the silicon substrate are diffused, to provide a pn junction, and form electrodes on the light receiving surface of the silicon substrate and a surface opposite thereto, respectively. In the double-sided electrode type solar cell, it is also generally done to diffuse impurities of the same conductivity type as that of the silicon substrate in the silicon substrate at the back surface at a high concentration to provide high output by a back surface field effect.

Research and development have been conducted also for a back electrode type solar cell (for example, see PTL 1 (Japanese Patent Laying-Open No. 2006-332273) in which a silicon substrate has a light receiving surface on which an electrode is not formed and also has a back surface only on which an n electrode and a p electrode are formed. Such a back electrode type solar cell does not require formation of an electrode for interrupting the light incident upon the light receiving surface of the silicon substrate, and therefore, the conversion efficiency of the solar cell is expected to be improved. Furthermore, technical development has also been advanced for a solar cell with an interconnection sheet in which an electrode of the above-described back electrode type solar cell is connected to an interconnection of an interconnection sheet.

### CITATION LIST

### Patent Literature

PTL 1: Japanese Patent Laying-Open No. 2006-332273

### SUMMARY OF INVENTION

### Technical Problem

An electrode of a back electrode type solar cell and an interconnection of an interconnection sheet are generally made of a metal material, which however has characteristics of causing ion migration that the metal material ionized by an electric field precipitates along the electric field direction. The likelihood of occurrence of this ion migration depends on the type of metal material and the strength of the electric field when ambient temperature and humidity are constant.

Furthermore, it has also been found that a pitch between a p electrode and an n electrode is closely related to the conversion efficiency. The smaller the pitch between the electrodes is, the higher the conversion efficiency is. In contrast, when the pitch between the electrodes is reduced, the strength of the electric field generated between the electrodes is increased. This facilitates ion migration to cause, for example, a short circuit to occur between the electrodes by needlelike substances formed from metal ions precipitated by ion migration, with the result that the conversion efficiency may be decreased.

In light of the above-described circumstances, an object of the present invention is to provide a solar cell, a solar cell with an interconnection, a solar cell module, and a method of manufacturing a solar cell with an interconnection, by which deterioration in the characteristics resulting from ion migration can be suppressed with stability.

### Solution To Problem

The present invention provides a solar cell including a substrate; a first electrode disposed on one of surfaces of the substrate; and a first covering layer covering a surface of the first electrode. The first covering layer is made of a material by which ion migration is less likely to occur as compared with a metal material forming the first electrode.

According to the solar cell of the present invention, it is preferable that the first covering layer is made of a conductive material.

Furthermore, according to the solar cell of the present invention, it is preferable that the solar cell is a back electrode type solar cell.

Furthermore, the solar cell of the present invention further includes a second electrode disposed on one of surfaces of the substrate and a second covering layer covering a surface of the second electrode. It is preferable that the second electrode is different in polarity from the first electrode, and the second covering layer is made of a material by which ion migration is less likely to occur as compared with a metal material forming the second electrode.

Furthermore, according to the solar cell of the present invention, it is preferable that the second covering layer is made of a conductive material.

Furthermore, the present invention provides a solar cell with an interconnection that includes a solar cell including a substrate, and a first electrode disposed on one of surfaces of the substrate; a first interconnection member electrically connected to the first electrode; and a first covering layer covering at least a part of a surface of the first electrode. The first covering layer is made of a material by which ion migration is less likely to occur as compared with a metal material forming the first electrode. The first interconnection member is greater in width than the first electrode.

Furthermore, the present invention provides a solar cell with an interconnection that includes a solar cell including a substrate, a first electrode disposed on one of surfaces of the substrate, and a second electrode disposed on one of the surfaces of the substrate and being different in polarity from the first electrode; a first interconnection member electrically connected to the first electrode; a second interconnection member electrically connected to the second electrode; a first covering layer covering at least a part of a surface of the first electrode; and a second covering layer covering at least a part of a surface of the second electrode. The first covering layer is made of a material by which ion migration is less likely to occur as compared with a metal material forming the first electrode. The second covering layer is made of a material by which ion migration is less likely to occur as compared with a metal material forming the second electrode. The first interconnection member is greater in width than the first electrode, and the second interconnection member is greater in width than the second electrode. In this case, it is preferable that the first electrode and the second electrode are disposed adjacent to each other, and the first covering layer covers at least a part of a surface of the first electrode on a side adjacent to the second electrode. Furthermore, it is preferable that the first interconnection member and the second interconnection member are disposed adjacent to each other, and the first covering layer covers at least a part of a surface of a corner portion in an end, on a side adjacent to the second interconnection member, of the first interconnection member connected to the first electrode.

Furthermore, the present invention provides a solar cell module including a solar cell with an interconnection as described in any of the above.

Furthermore, the present invention provides a method of manufacturing a solar cell with an interconnection including a solar cell having an electrode disposed on one of surfaces of a substrate, and an interconnection member. The method includes the steps of: disposing, on at least one of the electrode and the interconnection member, a covering member made of a material by which ion migration is less likely to occur as compared with a metal material forming the electrode; and covering a surface of the electrode by a covering layer formed by heating, melting and then solidifying the covering member, and electrically connecting the electrode and the interconnection member.

Furthermore, according to the method of manufacturing a solar cell with an interconnection of the present invention, it is preferable that the covering member is made of a brazing material or a conductive adhesive material that is lower in melting point than the metal material forming the electrode and the interconnection member.

Furthermore, according to the method of manufacturing a solar cell with an interconnection of the present invention, it is preferable that the interconnection member is greater in width than the electrode.

### Advantageous Effects Of Invention

According to the present invention, it becomes possible to provide a solar cell, a solar cell with an interconnection, a solar cell module, and a method of manufacturing a solar cell with an interconnection, by which deterioration in characteristics resulting from ion migration can be suppressed with stability.

### BRIEF DESCRIPTION OF DRAWINGS

FIG. 1 is a schematic cross-sectional view of a solar cell according to the first embodiment.

FIG. 2 is a diagram showing a relative value of ion migration sensitivity of each of various types of materials. FIGS. 3(a) to (e) each are a schematic cross-sectional view illustrating an example of a method of manufacturing a solar cell according to the first embodiment.

FIGS. 4(a) and (b) each are a schematic cross-sectional view illustrating an example of a method of manufacturing a solar cell with an interconnection according to the second embodiment.

FIG. 5 is a schematic cross-sectional view of a solar cell module according to the second embodiment.

FIG. 6 is a schematic cross-sectional view of a modification of the solar cell with an interconnection according to the second embodiment.

FIG. 7 is a schematic cross-sectional view of a modification of the solar cell module according to the second embodiment.

FIGS. 8(a) to (d) each are a schematic cross-sectional view illustrating an example of a method of manufacturing an interconnection sheet.

FIG. 9 is a schematic cross-sectional view of another modification of the solar cell with an interconnection according to the second embodiment.

FIG. 10 is a schematic cross-sectional view of still another modification of the solar cell module according to the second embodiment.

FIG. 11 is a schematic cross-sectional view of a solar cell with an interconnection according to the third embodiment.

FIG. 12 is a schematic cross-sectional view of a solar cell module according to the third embodiment.

FIG. 13 is a schematic cross-sectional view of a modification of the solar cell with an interconnection according to the third embodiment.

FIG. 14 is a schematic cross-sectional view of a modification of the solar cell module according to the third embodiment.

### DESCRIPTION OF EMBODIMENTS

The embodiments of the present invention will be hereinafter described. In the accompanying drawings of the present invention, the same or corresponding components are designated by the same reference characters.

### First Embodiment

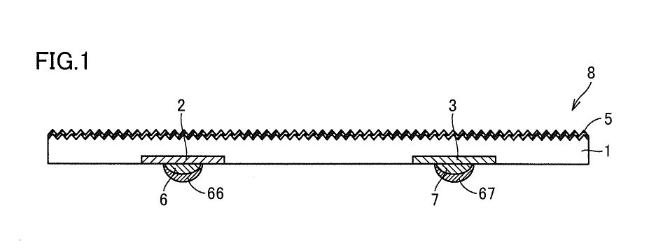

FIG. 1 shows a schematic cross-sectional view of a solar cell according to the first embodiment that is an example of the solar cell of the present invention. In this case, the solar cell according to the first embodiment is a back electrode type solar cell in which an electrode for n type 6 and an electrode for p type 7 that are different in polarity from each other (a negative polarity, a positive polarity) are provided on one of surfaces of a substrate 1, as shown in FIG. 1.

A solar cell 8 shown in FIG. 1 includes a substrate 1; an n type impurity diffusion region 2 and a p type impurity diffusion region 3 formed on one of surfaces (a back surface) of substrate 1; an electrode for n type 6 formed so as to be in contact with n type impurity diffusion region 2; and an electrode for p type 7 formed so as to be in contact with p type impurity diffusion region 3.

N type impurity diffusion region 2 and p type impurity diffusion region 3 each are formed in the shape of a strip extending along the front surface and/or the back surface of the plane of FIG. 1. In addition, n type impurity diffusion region 2 and p type impurity diffusion region 3 are disposed on the back surface of substrate 1 at a prescribed distance from each other.

Electrode for n type 6 and electrode for p type 7 each are also formed in the shape of a strip extending along the front surface and/or the back surface of the plane of FIG. 1. Electrode for n type 6 and electrode for p type 7 are formed along n type impurity diffusion region 2 and p type impurity diffusion region 3, respectively.

The surface of electrode for n type 6 is covered by a covering layer 66 while the surface of electrode for p type 7 is covered by a covering layer 67. In this case, covering layer 66 is made of a material by which ion migration is less likely to occur as compared with the metal material forming electrode for n type 6 while covering layer 67 is made of a material by which ion migration is less likely to occur as compared with the metal material forming electrode for p type 7.

Substrate 1 has a light receiving surface on which a concavo-convex structure such as a texture structure is formed, and an antireflection film 5 is formed so as to cover this concavo-convex structure. Substrate 1 has a back surface on which, for example, a passivation film and the like may be formed.

In the solar cell according to the first embodiment, the surface of electrode for n type 6 is covered by covering layer 66 made of a material by which ion migration is less likely to occur as compared with the metal material forming electrode for n type 6 while the surface of electrode for p type 7 is covered by covering layer 67 made of a material by which ion migration is less likely to occur as compared with the metal material forming electrode for p type 7. Consequently, it becomes possible to suppress deterioration in characteristics of the solar cell resulting from, for example, occurrence of an electrical short-circuit between electrode for n type 6 and electrode for p type 7 by needlelike substances generated from each surface of electrode for n type 6 and electrode for p type 7 due to ion migration.

In addition, covering layer 66 only has to cover at least a part of the surface of electrode for n type 6 and covering layer 67 only has to cover at least a part of the surface of electrode for p type 7. It is however preferable that covering layer 66 covers the entire surface of electrode for n type 6 while covering layer 67 covers the entire surface of electrode for p type 7, for the purpose of stably suppressing deterioration in the characteristics of the solar cell that results from ion migration.

It is preferable that covering layer 66 and covering layer 67 each are made of a conductive material. In the case where covering layer 66 and covering layer 67 each are made of a conductive material, the surfaces of electrode for n type 6 and electrode for p type 7 are covered by covering layer 66 and covering layer 67, respectively, that are made of a conductive material having the same electric potential, thereby allowing suppression of electrical field generation on the surfaces of electrode for n type 6 and electrode for p type 7. Consequently, since it becomes possible to suppress precipitation of metal ions by ion migration from each of electrode for n type 6 and electrode for p type 7, deterioration in characteristics of the solar cell resulting from ion migration can be suppressed with stability.

Covering layers 66 and 67 each may be made of an insulating material. It is to be noted that, when covering layers 66 and 67 each are made of an insulating material, it is preferable to employ such a material that can suppress entrance of metal ions precipitated by ion migration from electrode for n type 6 and electrode for p type 7 into covering layers 66 and 67, respectively. Accordingly, since covering layers 66 and 67 can prevent entrance of the metal ions precipitated by ion migration from electrode for n type 6 and electrode for p type 7 into covering layer 66 and covering layer 67, respectively, it becomes possible to stably suppress deterioration in the characteristics of the solar cell resulting from ion migration. In addition, the material that can suppress entrance of metal ions precipitated by ion migration may, for example, be a material that is low in halogen ion content, and the like.

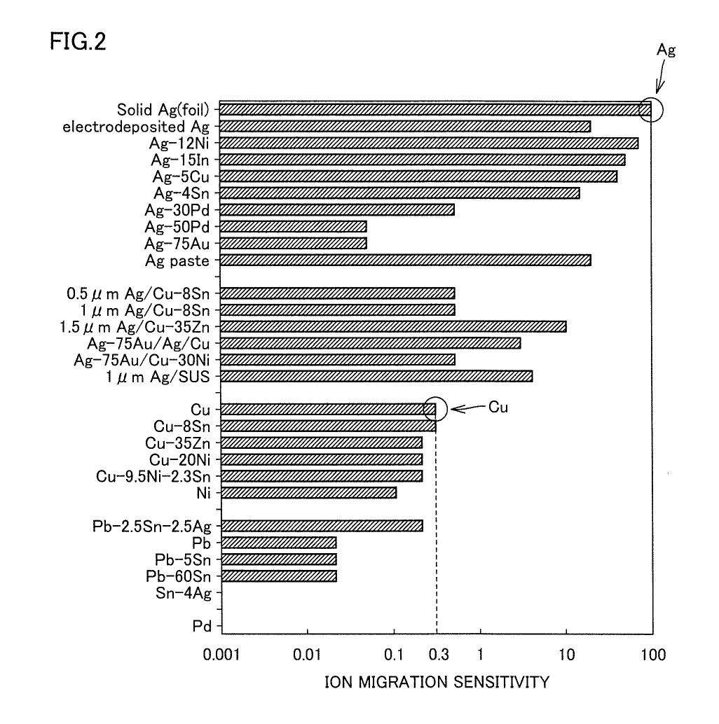

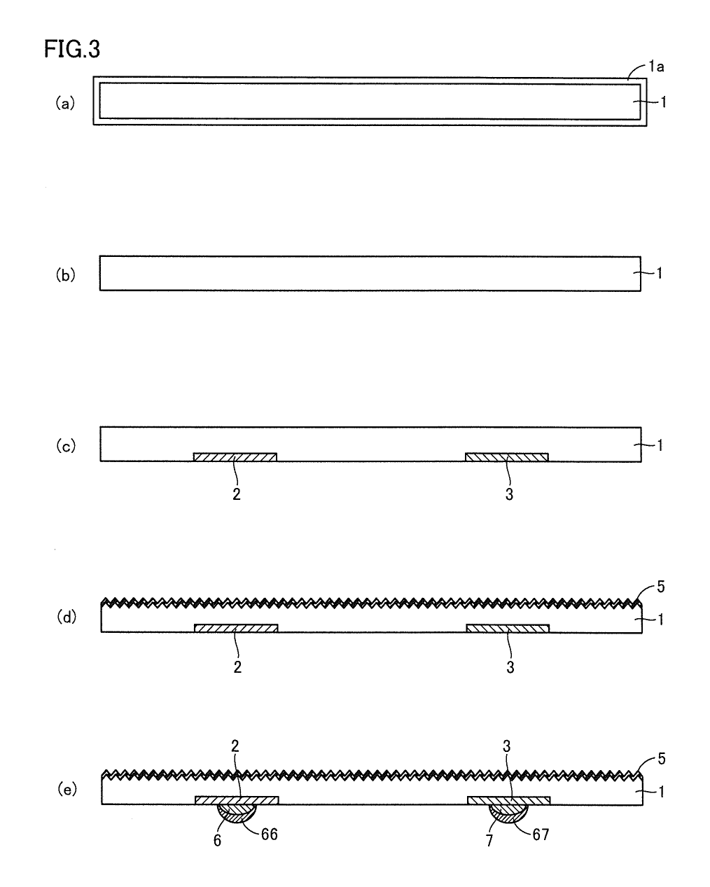

FIG. 2 shows a relative value of ion migration sensitivity of each of various types of materials. FIG. 2 is a diagram showing a relative value of ion migration sensitivity of each of various types of metal materials, assuming that the ion migration sensitivity of silver (Solid Ag (foil)) is set at 100. In FIG. 2, the vertical axis shows various types of materials while the horizontal axis shows a relative value of ion migration sensitivity of each of various types of materials. It is to be noted that FIG. 2 is based on the description on page 3 in “Corrosion Center News No. 017” (Sep. 1, 1998) edited by Japan Society of Corrosion Engineering. Also, the horizontal axis in FIG. 2 is a logarithmic axis.

For example, when electrode for n type 6 and electrode for p type 7 each are made of silver, as shown in FIG. 2, the relative value of the ion migration sensitivity of the metal material forming electrode for n type 6 and electrode for p type 7 is set at 100. In this case, the material used to form covering layer 66 and covering layer 67 may be, for example, a material having a relative value of the ion migration sensitivity lower than 100 (see FIG. 2).

Referring to the schematic cross-sectional views in FIGS. 3(a) to (e), an example of the method of manufacturing a solar cell according to the first embodiment will be hereinafter described.

First, as shown in FIG. 3(a), substrate 1 having a slice damage la formed on the surface thereof is prepared, for example, by slicing an ingot. In this case, substrate 1 may be, for example, a silicon substrate made of polycrystalline silicon, monocrystalline silicon or the like having n type conductivity or p type conductivity.

Then, as shown in FIG. 3(b), slice damage la on the surface of substrate 1 is removed. In this case, when substrate 1 is formed for example of the above-described silicon substrate, slice damage la can be removed by processes such as etching of the surface of the above-described sliced silicon substrate by mixed acid of a hydrogen fluoride aqueous solution and nitric acid or an alkaline aqueous solution such as sodium hydroxide. Although the size and shape of substrate 1 after removing slice damage 1 a are not particularly limited, substrate 1 having a thickness, for example, of 100 μm or more and 500 μm or less can be used.

Then, as shown in FIG. 3(c), n type impurity diffusion region 2 and p type impurity diffusion region 3 are formed on the back surface of substrate 1. In this case, n type impurity diffusion region 2 can be formed, for example, by methods such as vapor-phase diffusion using gas containing n type impurities or coating diffusion in which paste containing n type impurities is coated and then heat-treated. Furthermore, p type impurity diffusion region 3 can be formed, for example, by methods such as vapor-phase diffusion using gas containing p type impurities or coating diffusion in which paste containing p type impurities is coated and then heat-treated.

As to the gas containing n type impurities, for example, the gas containing n type impurities such as phosphorus like POCl₃ can be used. As to the gas containing p type impurities, for example, the gas containing p type impurities such as boron like BBr₃ can be used.

N type impurity diffusion region 2 is not particularly limited as long as it contains n type impurities and shows n type conductivity. N type impurities may be made, for example, of phosphorus and the like.

P type impurity diffusion region 3 is not particularly limited as long as it contains p type impurities and shows p type conductivity. P type impurities may be made, for example, of boron, aluminum, and/or the like.

A passivation film may be formed on the back surface of substrate 1 having n type impurity diffusion region 2 and p type impurity diffusion region 3 formed thereon. The passivation film can be produced, for example, using a method such as a thermal oxidation method or a plasma CVD (Chemical Vapor Deposition) method, for example, by forming a silicon nitride film, a silicon oxide film, or a laminated body of the silicon nitride film and the silicon oxide film. The passivation film can be formed to have a thickness of 0.05 μm or more and 1 μm or less, for example.

Then, as shown in FIG. 3(d), after a concavo-convex structure such as a texture structure is formed on the entire light receiving surface of substrate 1, antireflection film 5 is formed on the concavo-convex structure.

In this case, the texture structure can be formed, for example, by etching the light receiving surface of substrate 1. For example, when substrate 1 is a silicon substrate, the texture structure can be formed by etching the light receiving surface of substrate 1 using an etching solution obtained by adding isopropyl alcohol to an alkaline aqueous solution such as sodium hydroxide or potassium hydroxide and then heating the resultant solution, for example, to 70° C. or higher and 80° C. or lower.

Antireflection film 5 can be formed, for example, by the plasma CVD method or the like. Although antireflection film 5 can be made, for example, of a silicon nitride film and the like, the material is not limited thereto.

When a passivation film is formed on the back surface of substrate 1, a part of the passivation film on the back surface of substrate 1 may be removed to thereby provide a contact hole through which at least a part of the surface of n type impurity diffusion region 2 and at least a part of the surface of p type impurity diffusion region 3 are exposed.

A contact hole can be provided, for example, by the method using a photolithography technique to form, on the passivation film, a resist pattern having an opening in a portion corresponding to the area where the contact hole is provided, and then removing the passivation film through the opening of the resist pattern by etching and the like; the method of applying etching paste to a portion of the passivation film corresponding to the portion where the contact hole is provided, which is then heated for etching and removing the passivation film; or the like.

Then, as shown in FIG. 3(e), electrode for n type 6 and electrode for p type 7 are formed that are in contact with n type impurity diffusion region 2 and p type impurity diffusion region 3, respectively, on the back surface of semiconductor substrate 1.

Electrode for n type 6 and electrode for p type 7 each can be formed, for example, by applying silver paste to n type impurity diffusion region 2 and p type impurity diffusion region 3, respectively, so as to be in contact therewith, and then, firing the silver paste. Consequently, electrode for n type 6 and electrode for p type 7 each can be formed to contain silver at least in the surfaces thereof. It is needless to say that electrode for n type 6 and electrode for p type 7 may not contain silver at least in the surfaces thereof.

Then, covering layer 66 is formed on the surface of electrode for n type 6 while covering layer 67 is formed on the surface of electrode for p type 7. The method of forming covering layer 66 and covering layer 67 is not particularly limited as long as it allows at least a part of the surface of each of electrode for n type 6 and electrode for p type 7 to be covered. In the manner as described above, the solar cell according to the first embodiment can be manufactured.

In addition, the concept of the back electrode type solar cell in the present invention includes not only such a configuration in which both of an electrode for n type and an electrode for p type are formed only on one of the surfaces (back surface side) of the substrate described above, but also every configuration of the so-called back-contact type solar cell (a solar cell having the structure in which electric current is taken out from the back surface side opposite to the light receiving surface side of the solar cell) such as an MWT (Metal Wrap Through) cell (a solar cell having the configuration in which a part of the electrode is disposed in a through hole provided in the substrate).

### Second Embodiment

The solar cell with an interconnection according to the second embodiment is characterized in that a plurality of solar cells 8 according to the first embodiment are electrically connected by an interconnection member.

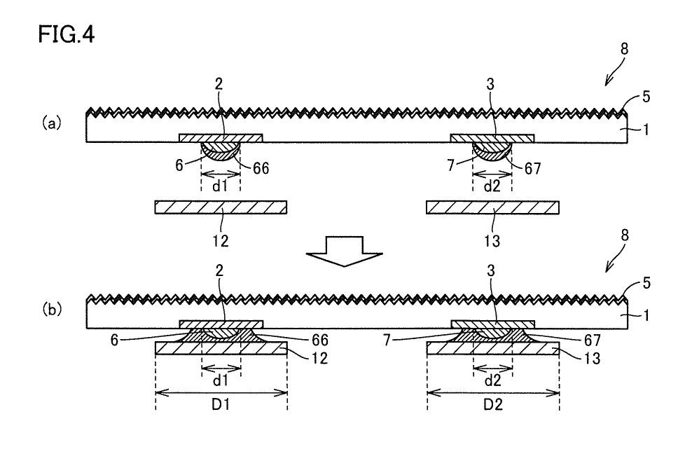

Referring to the schematic cross-sectional views in FIGS. 4(a) and 4(b), an example of the method of manufacturing a solar cell with an interconnection according to the second embodiment will be hereinafter described. First, as shown in FIG. 4(a), solar cell 8 according to the first embodiment is disposed above each of the surfaces of an interconnection member for n type 12 and an interconnection member for p type 13. In this case, solar cell 8 according to the first embodiment is configured such that electrode for n type 6 is located above the surface of interconnection member for n type 12 and electrode for p type 7 is located above the surface of interconnection member for p type 13.

Although interconnection member for n type 12 and interconnection member for p type 13 are not particularly limited as long as each member is made of a conductive material, it is preferable that the conductive material forming interconnection member for n type 12 and interconnection member for p type 13 is made of a material by which ion migration is less likely to occur as compared with the metal material forming electrode for n type 6 and electrode for p type 7. For example, when the metal material forming electrode for n type 6 and electrode for p type 7 is silver, copper that is lower in ion migration sensitivity than silver can be suitably used as a material for interconnection member for n type 12 and interconnection member for p type 13 (see FIG. 2).

Furthermore, the shapes of interconnection member for n type 12 and interconnection member for p type 13 are not particularly limited as long as interconnection member for n type 12 and interconnection member for p type 13 can be electrically connected to electrode for n type 6 and electrode for p type 7, respectively. It is however preferable that, for example, a width D1 of interconnection member for n type 12 is greater than a width d1 of electrode for n type 6 while a width D2 of interconnection member for p type 13 is greater than a width d2 of electrode for p type 7, as described below.

When a plurality of electrodes for n type 6 and a plurality of electrodes for p type 7 are provided, a plurality of interconnection members for n type 12 and a plurality of interconnection members for p type 13 may also be provided so as to have shapes corresponding to those of their respective electrodes. Furthermore, interconnection member for n type 12 may include an interconnection member and the like for electrically connecting the plurality of interconnection members for n type 12 to each other while interconnection member for p type 13 may also include an interconnection member and the like for electrically connecting the plurality of interconnection members for p type 13 to each other. Furthermore, interconnection member for n type 12 and interconnection member for p type 13 may each include an interconnection member and the like for electrically connecting a plurality of solar cells 8.

In the present embodiment, interconnection member for n type 12 and interconnection member for p type 13 each are formed in the shape of a strip extending along the front surface and/or the back surface of the plane of FIG. 4. Therefore, in the direction of the normal to the plane of FIG. 4, the surface of interconnection member for n type 12 faces the surface of covering layer 66 made of a conductive material and covering the surface of electrode for n type 6 while the surface of interconnection member for p type 13 faces the surface of covering layer 67 made of a conductive material and covering the surface of electrode for p type 7.

Width D1 of interconnection member for n type 12 is greater than width d1 of electrode for n type 6 while width D2 of interconnection member for p type 13 is greater than width d2 of electrode for p type 7. In addition, width d1 of electrode for n type 6, width d2 of electrode for p type 7, width D1 of interconnection member for n type 12, and width D2 of interconnection member for p type 13 each correspond to a length extending in the direction orthogonal (the horizontal direction on the plane of FIG. 4) to the extending direction of these electrodes and members (the normal direction to the plane of FIG. 4).

Width d1 of electrode for n type 6 and width d2 of electrode for p type 7 each can be set at 100 μm or more and 300 μm or less, for example. Furthermore, the thickness of each of electrode for n type 6 and electrode for p type 7 can be set at, for example, 5 μm or more and 15 μm or less. Width d1 of electrode for n type 6 and width d2 of electrode for p type 7 do not necessarily have the same value, and also, the thickness of electrode for n type 6 and the thickness of electrode for p type 7 do not necessarily have the same value.

Width D1 of interconnection member for n type 12 and width D2 of interconnection member for p type 13 each can be set at, for example, 300 μm or more and 600 μm or less. Furthermore, the thickness of interconnection member for n type 12 and the thickness of interconnection member for p type 13 each can be set at, for example, 10 μm or more and 50 μm or less. Width D1 of interconnection member for n type 12 and width D2 of interconnection member for p type 13 do not necessarily have the same value, while the thickness of interconnection member for n type 12 and the thickness of interconnection member for p type 13 do not necessarily have the same value.

Then, covering layer 66 covering the surface of electrode for n type 6 is provided so as to be in contact with the surface of interconnection member for n type 12 while covering layer 67 covering the surface of electrode for p type 7 is provided so as to be in contact with the surface of interconnection member for p type 13. Then, covering layers 66 and 67 are heated and melted, and then, solidified. Consequently, covering layers 66 and 67 each are brought into a melted state, and becomes wet and spread over the surfaces of interconnection member for n type 12 and interconnection member for p type 13, respectively, and then solidified in the wet and spread state, for example, by cooling and the like. Then, as shown in FIG. 4(b), by covering layers 66 and 67 solidified in the wet and spread state, electrode for n type 6 and electrode for p type 7 are bonded to interconnection member for n type 12 and interconnection member for p type 13, respectively, to establish an electrical connection. In the manner as described above, the solar cell with an interconnection according to the second embodiment can be manufactured.

As described above, width D1 of interconnection member for n type 12 is greater than width d1 of electrode for n type 6 while width D2 of interconnection member for p type 13 is greater than width d2 of electrode for p type 7. Accordingly, since covering layers 66 and 67 in the melted state becomes sufficiently wet and spread over the surfaces of interconnection member for n type 12 and interconnection member for p type 13, respectively, solidified covering layers 66 and 67 can cover the surfaces of electrode for n type 6 and electrode for p type 7, respectively.

In other words, it is preferable that covering layers 66 and 67 are made of a brazing material or an electrically-conductive adhesive material that is melted by heating. It is particularly preferable that covering layers 66 and 67 are made of a conductive material for the purpose of establishing an electrical connection between electrode for n type 6 and interconnection member for n type 12, and between electrode for p type 7 and interconnection member for p type 13. Furthermore, it is preferable that the melting points of covering layers 66 and 67 made of a brazing material or a conductive adhesive material are lower than the melting point of the electrode (electrode for n type 6, electrode for p type 7) and the melting point of the interconnection member (interconnection member for n type 12, interconnection member for p type 13). In this case, since covering layers 66 and 67 can be melted without deforming the electrode or the interconnection member, covering layers 66 and 67 tend to be able to readily cover the surfaces of the electrode and the interconnection member.

Furthermore, in the case where the metal material forming the electrode (electrode for n type 6, electrode for p type 7) is silver, it is preferable to use solder that is a tin alloy for covering layers 66 and 67. In this case, in addition to the above-described effect caused by covering layers 66 and 67 made of a conductive material, the voltage drop in the connecting portion between the electrode and the interconnection member can be suppressed, thereby allowing improvement in the output power of the solar cell with an interconnection.

Although an explanation has been given in the above with regard to the case of using solar cell 8 according to the first embodiment in which covering layers 66 and 67 are disposed on the surfaces of electrode for n type 6 and electrode for p type 7, respectively, covering layers 66 and 67 may be disposed only on the surface of the interconnection member (interconnection member for n type 12, interconnection member for p type 13), or may be disposed on each of the surfaces of the electrode (electrode for n type 6, electrode for p type 7) and the interconnection member (interconnection member for n type 12, interconnection member for p type 13). Furthermore, covering layers 66 and 67 may be disposed not only on the surface of the electrode (electrode for n type 6, electrode for p type 7) but also on the side surface of the electrode or on the back surface of semiconductor substrate 1 in proximity to the electrode.

Furthermore, although an explanation has been given in the above with regard to the case where solar cell 8 according to the first embodiment is used, the solar cell with an interconnection according to the second embodiment can be manufactured by the method including the steps of: disposing a covering member on at least one of an electrode and an interconnection member, the covering member being made of a material by which ion migration is less likely to occur as compared with a metal material forming the electrode; and covering the surface of the electrode by the covering layer that is formed by heating, melting and then solidifying the covering member, and electrically connecting the electrode and the interconnection member. In addition, the covering member is heated and melted, and becomes wet and spread over the surface of the interconnection member, and then solidified, thereby being formed as a covering layer covering the surface of the electrode.

If the covering member is melted by heating and becomes wet and spread over the surface of the interconnection member to thereby allow formation of a covering layer covering the surface of the electrode, the covering member can be disposed, for example, only on the side of the electrode without disposing the covering member on the surface of the electrode. Consequently, even when the electrode has to be directly brought into contact with the interconnection member for reasons that the covering member is made of an insulating material or the electrical resistance is high, the covering layer can be disposed.

In this case, it is preferable that the covering member is made of a brazing material or a conductive adhesive material that is lower in melting point than a metal material forming the electrode and the interconnection member. Furthermore, it is also preferable that the covering member made of a brazing material or a conductive adhesive material is lower in melting point than the electrode (electrode for n type 6, electrode for p type 7) and the interconnection member (interconnection member for n type 12, interconnection member for p type 13). In this case, since the covering member can be melted without deforming the electrode and the interconnection member, the covering member tends to be able to readily cover the surfaces of the electrode and the interconnection member.

Furthermore, it is preferable also in this method that the interconnection member is greater in width than the electrode. In this case, it is more likely that the covering member melted by heating can cover the surface of the electrode without this covering member extending beyond the surface of the interconnection member.

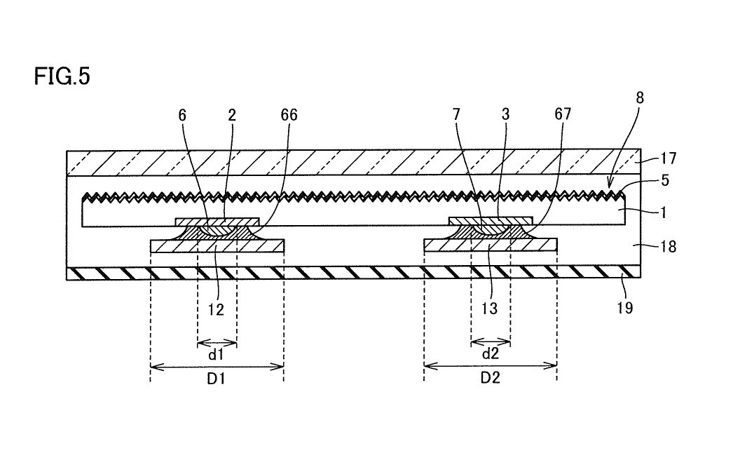

Then, for example, as shown in the schematic cross-sectional view in FIG. 5, the solar cell with an interconnection according to the second embodiment is sealed in a sealing material 18 between a transparent substrate 17 and a back surface protection material 19, so that the solar cell module according to the second embodiment can be manufactured.

In this case, transparent substrate 17 may be, for example, a substrate such as a glass substrate through which light incident on the solar cell module can be transmitted. Sealing material 18 may be, for example, a resin such as ethylenevinyl acetate through which light incident on the solar cell module can be transmitted. Back surface protection material 19 may be, for example, a member such as a polyester film that can protect the solar cell with an interconnection.

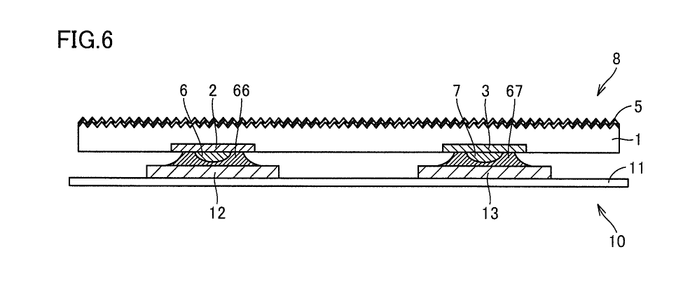

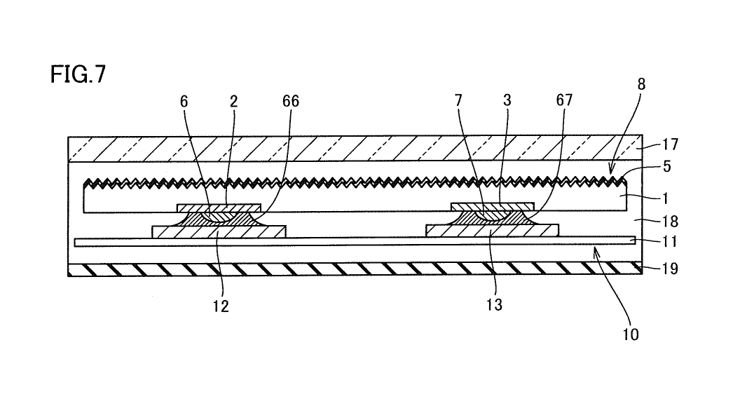

FIG. 6 shows a schematic cross-sectional view of a modification of the solar cell with an interconnection according to the second embodiment while FIG. 7 shows a schematic cross-sectional view of a modification of the solar cell module according to the second embodiment. The solar cell with an interconnection shown in FIG. 6 and the solar cell module shown in FIG. 7 are characterized in that a plurality of solar cells 8 are electrically connected in series using an interconnection sheet 10 in which an interconnection member for n type 12 and an interconnection member for p type 13 are arranged on the surface of an insulating base material 11. Such interconnection sheet 10 is suitable since a large number of electrodes and interconnection members can be electrically connected with ease and reliability.

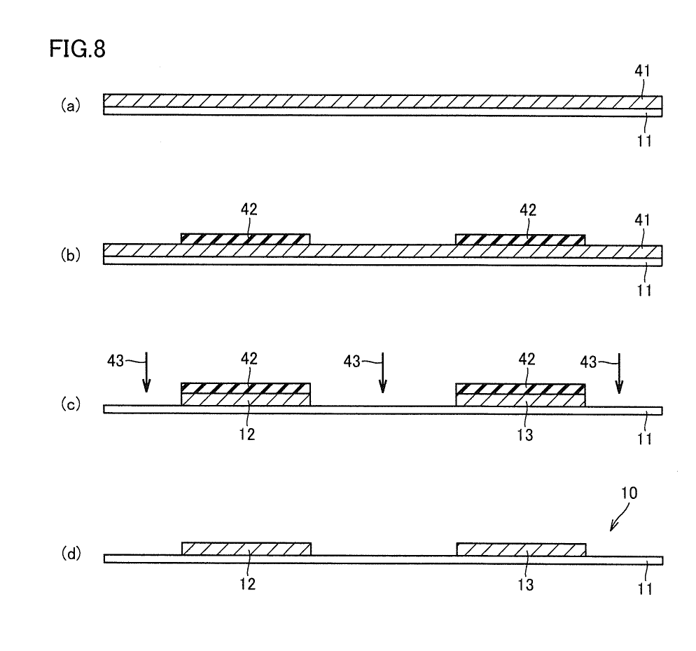

Referring to the schematic cross-sectional views in FIGS. 8(a) to 8(d), an example of the method of manufacturing interconnection sheet 10 will be hereinafter described.

First, as shown in FIG. 8(a), a conductive layer 41 made of a conductive material is formed on the surface of insulating base material 11.

In this case, although insulating base material 11 may be, for example, a substrate made of a resin such as polyester, polyethylene naphthalate or polyimide, the material thereof is not limited thereto. The thickness of insulating base material 11 can be set at 10 μm or more and 200 μm or less, for example.

Then, as shown in FIG. 8(b), a resist 42 is fainted on conductive layer 41 on the surface of insulating base material 11.

In this case, resist 42 is formed to have an opening in a portion other than that where interconnection members in interconnection sheet 10 such as interconnection member for n type 12 and interconnection member for p type 13 are left unremoved. For example, resist 42 can be made of a conventionally known material, and for example, may be made of a material obtained by curing a resin that has been applied to a predetermined position by the method such as screen printing, dispenser application, ink jet application or the like.

Then, as shown in FIG. 8(c), a portion of conductive layer 41 that is not covered by resist 42 is removed in the direction of an arrow 43, thereby patterning conductive layer 41, to form an interconnection member of interconnection sheet 10 such as interconnection member for n type 12 and interconnection member for p type 13 from the remainder of conductive layer 41.

In this case, conductive layer 41 can be removed, for example, by wet etching and the like using an acid solution or an alkaline solution.

Then, as shown in FIG. 8(d), resist 42 is entirely removed from the surfaces of interconnection member for n type 12 and interconnection member for p type 13. Consequently, interconnection sheet 10 is produced in which interconnection member for n type 12 and interconnection member for p type 13 are formed on insulating base material 11. In addition to interconnection member for n type 12 and interconnection member for p type 13, the interconnection member formed on insulating base material 11 may include, for example, an interconnection member electrically connecting a plurality of interconnection members for n type 12, an interconnection member electrically connecting a plurality of interconnection members for p type 13, an interconnection member for electrically connecting a plurality of solar cells 8, and the like.

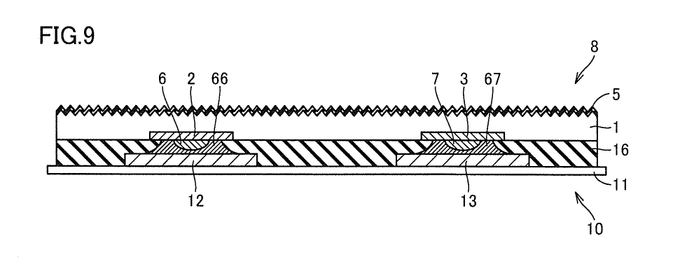

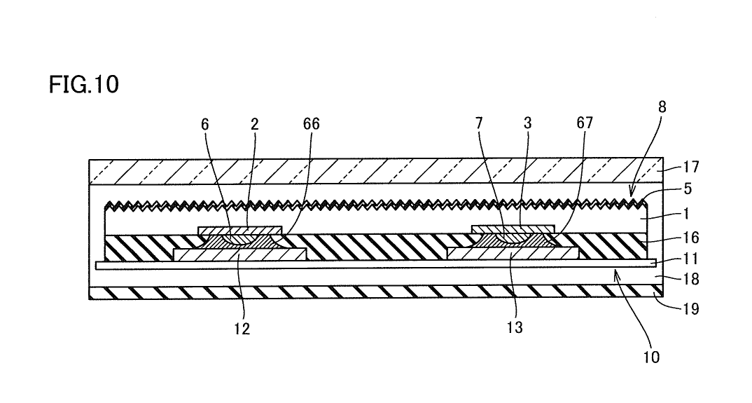

FIG. 9 shows a schematic cross-sectional view of another modification of the solar cell with an interconnection according to the second embodiment while FIG. 10 shows a schematic cross-sectional view of still another modification of the solar cell module according to the second embodiment. The solar cell with an interconnection shown in FIG. 9 and the solar cell module shown in FIG. 10 are characterized in that an insulating material 16 is disposed between substrate 1 and insulating base material 11 while solar cell 8 and interconnection sheet 10 are joined by insulating material 16.

In this case, insulation material 16 is not particularly limited as long as it is an insulative material, and for example, materials such as an electrically insulating thermosetting and/or photocurable resin composition including an epoxy resin, an acrylic resin or a mixed resin of the epoxy resin and the acrylic resin may be used as a resin component. Furthermore, as a component other than the resin component, insulating material 16 may contain one or more types of conventionally known additives, for example, a curing agent and the like.

It is preferable to employ, as insulating material 16, a material that prevents entrance of metal ions precipitated by ion migration, such as an insulating material that is low in content of halogen ions that promote ion migration. In this case, it becomes possible to stably suppress deterioration in characteristics of the solar cell with an interconnection and the solar cell module that is caused by ion migration.

Furthermore, it is preferable to use an insulative adhesive material as insulating material 16. In this case, since solar cell 8 and interconnection sheet 10 can be more firmly bonded to each other by insulating material 16, the mechanical strength of the solar cell with an interconnection and the solar cell module can be improved while entrance of moisture into the region between electrode for n type 6 and electrode for p type 7 can also be suppressed. Consequently, it is more likely that occurrence of ion migration can be further suppressed.

In addition, the solar cell with an interconnection shown in FIG. 9 and the solar cell module shown in FIG. 10 each can be manufactured by applying insulating material 16 to at least one of solar cell 8 and interconnection sheet 10 and then bonding solar cell 8 and interconnection sheet 10 to each other.

As described above, also in the solar cell with an interconnection and the solar cell module according to the second embodiment that are shown in FIGS. 4 to 7 and FIGS. 9 and 10, the surface of electrode for n type 6 is covered by covering layer 66 made of a material by which ion migration is less likely to occur as compared with the metal material forming electrode for n type 6, while the surface of electrode for p type 7 is covered by covering layer 67 made of a material by which ion migration is less likely to occur as compared with the metal material forming electrode for p type 7. Accordingly, it becomes possible to suppress deterioration in characteristics that is caused by occurrence of an electrical short-circuit between electrode for n type 6 and electrode for p type 7 by needlelike substances generated from each surface of electrode for n type 6 and electrode for p type 7 due to ion migration.

Furthermore, in the solar cell with an interconnection and the solar cell module according to the second embodiment that are shown in FIGS. 4 to 7 and FIGS. 9 and 10, it is preferable that electrode for n type 6 and electrode for p type 7 are disposed adjacent to each other; covering layer 66 covers at least a part of the surface of electrode for n type 6 that is adjacent to electrode for p type 7; and covering layer 67 covers at least a part of the surface of electrode for p type 7 that is adjacent to electrode for n type 6. In this case, covering layers 66 and 67 tend to cover at least a part of the surface of electrode for n type 6 and at least a part of the surface of electrode for p type 7, respectively, between which the distance is relatively short. Accordingly, it is more likely that deterioration in the characteristics can be suppressed that results from occurrence of an electrical short-circuit between electrode for n type 6 and electrode for p type 7 caused by needlelike substances generated due to ion migration, and the like. Since the description other than the above in the present embodiment is the same as that of the first embodiment, descriptions thereof will not be repeated.

### Third Embodiment

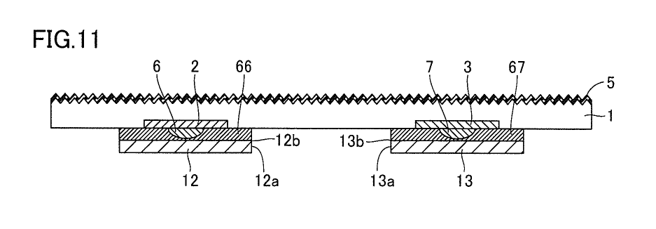

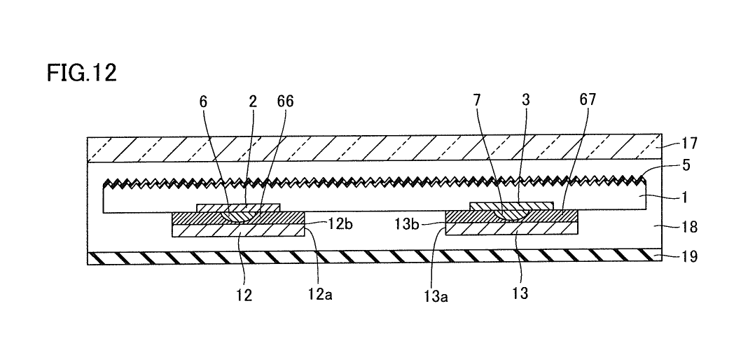

FIG. 11 shows a schematic cross-sectional view of a solar cell with an interconnection according to the third embodiment that is still another example of the solar cell with an interconnection of the present invention while FIG. 12 shows a schematic cross-sectional view of a solar cell module according to the third embodiment that is still another example of the solar cell module of the present invention.

In the solar cell with an interconnection and the solar cell module according to the third embodiment, electrode for n type 6 and electrode for p type 7 are disposed to face interconnection member for n type 12 and interconnection member for p type 13, respectively. Also, interconnection member for n type 12 and interconnection member for p type 13 are disposed adjacent to each other; covering layer 66 covers a part of the surface of a corner portion 12b in the end, on the side adjacent to interconnection member for p type 13, of interconnection member for n type 12 connected to electrode for n type 6; and covering layer 67 covers a part of the surface of a corner portion 13b in the end, on the side adjacent to interconnection member for n type 12, of interconnection member for p type 13 connected to electrode for p type 7.

In this case, the corner portion includes not only the so-called vertex angle, but also a side portion obtained by bending a plane. In the example shown in FIG. 11, corner portion 12b of interconnection member for n type 12 corresponds to a line of intersection of the surface of interconnection member for n type 12 facing electrode for n type 6 and a side surface 12a of interconnection member for n type 12 facing interconnection member for p type 13. Furthermore, corner portion 13b of interconnection member for p type 13 corresponds to a line of intersection of the surface of interconnection member for p type 13 facing electrode for p type 7 and a side surface 13a of interconnection member for p type 13 facing interconnection member for n type 12.

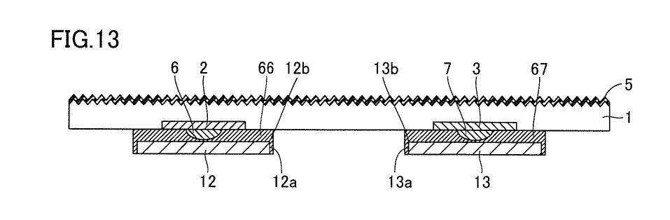

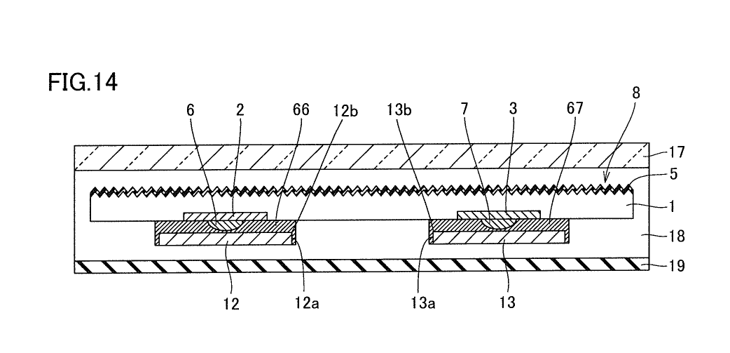

FIG. 13 shows a schematic cross-sectional view of a modification of the solar cell with an interconnection according to the third embodiment that is still another example of the solar cell with an interconnection of the present invention while FIG. 14 shows a schematic cross-sectional view of a modification of the solar cell module according to the third embodiment that is still another example of the solar cell module of the present invention.

Also in the modifications of the solar cell with an interconnection and the solar cell module according to the third embodiment, interconnection member for n type 12 and interconnection member for p type 13 are disposed adjacent to each other; covering layer 66 covers the entire surface of corner portion 12b in the end, on the side adjacent to interconnection member for p type 13, of interconnection member for n type 12 connected to electrode for n type 6; and covering layer 67 covers the entire surface of corner portion 13b in the end, on the side adjacent to interconnection member for n type 12, of interconnection member for p type 13 connected to electrode for p type 7.

It is generally known that in the electric field generated between two planes, the electric field is concentrated in the corner portion to thereby increase the electric field strength. As in the present embodiment, however, covering layers 66 and 67 made of a conductive material can suppress corner portions 12b and 13b of interconnection member for n type 12 and interconnection member for p type 13, respectively, from being exposed to the electric field, so that it becomes possible to suppress facilitation of ion migration in corner portions 12b and 13b of interconnection member for n type 12 and interconnection member for p type 13, respectively.

Accordingly, in the solar cell with an interconnection and the solar cell module shown in FIGS. 11 to 14, since occurrence of ion migration in each of interconnection member for n type 12 and interconnection member for p type 13 can be suppressed, it becomes possible to suppress deterioration in the characteristics of the solar cell with an interconnection and the solar cell module that is caused by ion migration.

It is preferable that covering layer 66 is made of a material by which ion migration is less likely to occur as compared with the material forming interconnection member for n type 12. In this case, since occurrence of ion migration in the portion of interconnection member for n type 12 in contact with covering layer 66 can be further suppressed, it is more likely to be able to stably suppress deterioration in the characteristics of the solar cell with an interconnection and the solar cell module that is caused by ion migration.

It is preferable that covering layer 67 is made of a material by which ion migration is less likely to occur as compared with the material forming interconnection member for p type 13. In this case, since occurrence of ion migration in the portion of interconnection member for p type 13 in contact with covering layer 67 can be suppressed, it is more likely to be able to stably suppress deterioration in the characteristics of the solar cell with an interconnection and the solar cell module that is caused by ion migration.

Description other than the above in the present embodiment is the same as those in the first and the second embodiments, and therefore, will not be repeated. It should be understood that the embodiments disclosed herein are illustrative and non-restrictive in every respect. The scope of the present invention is defined by the terms of the claims, rather than the description above, and is intended to include any modifications within the scope and meaning equivalent to the terms of the claims.

### INDUSTRIAL APPLICABILITY

The present invention can be applied to a solar cell, a solar cell with an interconnection, a solar cell module, and a method of manufacturing the solar cell with an interconnection.

### REFERENCE SIGNS LIST

1 substrate, 1a slice damage, 2 n type impurity diffusion region, 3 p type impurity diffusion region, 5 antireflection film, 6 electrode for n type, 7 electrode for p type, 8 solar cell, 10 interconnection sheet, 11 insulating base material, 12 interconnection member for n type, 13 interconnection member for p type, 12a, 13a side surface, 12b, 13b corner portion, 16 insulating material, 17 transparent substrate, 18 sealing material, 19 back surface protection material, 41 conductive layer, 42 resist, 43 arrow, 66, 67 covering layer.

1-13. (canceled)

14. A solar cell with an interconnection, comprising:
a back electrode type solar cell including a substrate, a first electrode and a second electrode being different in polarity from said first electrode disposed on one of surfaces of said substrate;
a first interconnection member electrically connected to said first electrode;
a second interconnection member electrically connected to said second electrode;
a first covering layer covering at least a part of a surface of said first electrode; and
a second covering layer covering at least a part of a surface of said second electrode, wherein
said first covering layer is made of a material by which ion migration is less likely to occur as compared with a metal material forming said first electrode,
said second covering layer is made of a material by which ion migration is less likely to occur as compared with a metal material forming said second electrode,
said first electrode and said second electrode are disposed adjacent to each other,
an insulating material is disposed between said first electrode and said second electrode adjacent to said first electrode so as to be in contact with a back surface of said back electrode type solar cell, and
said first covering layer is interposed in contact with the back surface of said back electrode type solar cell between said first electrode and said insulating material while said second covering layer is interposed in contact with the back surface of said back electrode type solar cell between said second electrode and said insulating material.

15. The solar cell according to claim 14, wherein said first covering layer and said second covering layer each are made of a conductive material.

16. The solar cell with an interconnection according to claim 14, wherein
said first interconnection member is greater in width than said first electrode, and
said second interconnection member is greater in width than said second electrode.

17. The solar cell with an interconnection according to claim 16, wherein
said first interconnection member is made of a metal material by which ion migration is less likely to occur as compared with the metal material forming said first electrode, and
said second interconnection member is made of a metal material by which ion migration is less likely to occur as compared with the metal material forming said second electrode.

18. The solar cell with an interconnection according to claim 16, wherein said first interconnection member and said second interconnection member each contain copper while said first electrode and said second electrode each contain silver.

19. The solar cell with an interconnection according to claim 14, wherein
said first interconnection member and said second interconnection member are disposed adjacent to each other, and
said first covering layer covers at least a part of a surface of a corner portion in an end, on a side adjacent to said second interconnection member, of said first interconnection member connected to said first electrode.

20. A solar cell module comprising the solar cell with an interconnection according to claim 14.

21. A method of manufacturing a solar cell with an interconnection, including a back electrode type solar cell in which a first electrode and a second electrode disposed adjacent to each other and being different in polarity from each other are disposed on one of surfaces of a substrate, and a first interconnection member and a second interconnection member adjacent to each other, said method comprising the steps of:
disposing, on at least one of said first electrode and said first interconnection member, a first covering member made of a conductive material by which ion migration is less likely to occur as compared with a metal material forming said first electrode;
disposing, on at least one of said second electrode and said second interconnection member, a second covering member made of a conductive material by which ion migration is less likely to occur as compared with a metal material forming said second electrode;
covering a surface of said first electrode by the first covering layer formed by heating, melting and then solidifying said first covering member, and electrically connecting said first electrode and said first interconnection member;
covering a surface of said second electrode by the second covering layer formed by heating, melting and then solidifying said second covering member, and electrically connecting said second electrode and said second interconnection member; and
disposing an insulating resin composition and curing said insulating resin composition to form an insulating material such that said insulating material is disposed between said first electrode and said second electrode adjacent to said first electrode so as to be in contact with a back surface of said back electrode type solar cell, said first covering layer is interposed in contact with the back surface of said back electrode type solar cell between said first electrode and said insulating material, and said second covering layer is interposed in contact with the back surface of said back electrode type solar cell between said second electrode and said insulating material.

22. The method of manufacturing a solar cell with an interconnection according to claim 21, wherein
said first covering member is made of a brazing material or a conductive adhesive material that is lower in melting point than the metal material forming said first electrode and said first interconnection member, and
said second covering member is made of a brazing material or a conductive adhesive material that is lower in melting point than the metal material forming said second electrode and said second interconnection member.

23. The method of manufacturing a solar cell with an interconnection according to claim 21, wherein said first interconnection member is greater in width than said first electrode while said second interconnection member is greater in width than said second electrode.
